(19) United States
(12) Patent Application Publication
(10) Pub. No.: US 2026/0291382 A1
(43) Pub. Date: Sep. 24, 2026

(54) SWITCHING CONTROL DEVICE AND POWER CONVERSION DEVICE

(71) Applicant: Mitsubishi Electric Corporation, Tokyo (JP)

(72) Inventor: Retsu SUGAWARA, Tokyo (JP)

(73) Assignee: Mitsubishi Electric Corporation, Tokyo (JP)

(21) Appl. No.: 19/472,132

(22) PCT Filed: Apr. 12, 2023
(86) PCT No.: PCT/JP2023/014907

§ 371 Date: Oct. 3, 2025

(51) Int. Cl. H02M 1/44; H02M 1/00; H02M 1/088; H03K 17/16

(52) U.S. Cl. CPC H02M 1/44; H02M 1/0043; H02M 1/088; H03K 17/165

(57) ABSTRACT

A switching control device includes: a frequency setting unit that sets a plurality of types of carrier frequencies and a frequency change period; and a control signal generation unit that controls a switching operation performed by a switching element by transitioning the plurality of types of carrier frequencies in the frequency change period. The frequency change period is set to be longer than a time width (window function width) determined by a reciprocal of a resolution bandwidth. In addition, when the average number of times of switching in the sections of the frequency change period is denoted by fave, the average number of times of switching in the sections cut out with the time width is denoted by fw, the resolution bandwidth is denoted by RBW, and m is an integer of 2 or more, fw is set to satisfy a relationship of fave−RBW/2<fw<fave+RBW/2.

### FIELD

The present disclosure relates to a switching control device that controls a switching operation of a switching element and a power conversion device.

### BACKGROUND

In a power conversion device that performs power conversion on the basis of a switching operation of a switching element, in a case where switching is performed at a certain switching frequency, electromagnetic noise is generated at a certain frequency and harmonic components of the frequency. In a product equipped with such a power conversion device, noise current standards are set on a product classification basis, and countermeasures are required when a noise current exceeds an upper limit value in the standards. As a general countermeasure, a noise filter having an anti-noise component such as a choke coil or a capacitor is possibly used, but in a case of using the noise filter, an increase in size of the device and an increase in cost are problems. In order to solve the problems, there has been conventionally proposed a power conversion device including a frequency changing device that repeatedly outputs a frequency changing pattern including a plurality of frequency values, and a controller that controls on/off of a switching element at a switching frequency in accordance with the frequency changing pattern output from the frequency changing device (see, for example, Patent Literature 1). There has also been proposed a power conversion device that sets a period of a frequency change pattern in order to obtain a noise reduction effect even under various measurement conditions and detection methods (see, for example, Patent Literature 2).

### CITATION LIST

### Patent Literature

Patent Literature 1: Japanese Patent Application Laid-open No. 2006-288103
Patent Literature 2: Japanese Patent Application Laid-open No. 2016-19322

### SUMMARY OF INVENTION

### Problem to be Solved by the Invention

Conventional power conversion devices reduce electromagnetic noise by using a plurality of switching frequencies, but a sufficient noise reduction effect may not be obtained depending on measurement conditions.

Therefore, a technique for obtaining a higher noise reduction effect under various measurement conditions is demanded.

The present disclosure has been made in view of the above, and an object thereof is to provide a switching control device capable of obtaining a higher noise reduction effect under various measurement conditions.

### Means to Solve the Problem

In order to solve the above problem and achieve the object, a switching control device according to the present disclosure is a switching control device that controls a switching operation performed by a switching element, and includes: a frequency setting unit that sets a plurality of types of carrier frequencies and a frequency change period; and a control unit that controls a switching operation performed by the switching element by transitioning the plurality of types of carrier frequencies in the frequency change period. The frequency change period is set to be longer than a time width determined by a reciprocal of a resolution bandwidth. In addition, when the average number of times of switching in sections of the frequency change period is denoted by fave, the average number of times of switching in sections cut out with the time width is denoted by fw, the resolution bandwidth is denoted by RBW, and m is an integer of 2 or more, the fw is set to satisfy a relationship of fave-RBW/2<fw<fave+RBW/2.

### Effects of the Invention

The switching control device according to the present disclosure achieves an effect that it is possible to obtain a higher noise reduction effect under various measurement conditions.

### BRIEF DESCRIPTION OF DRAWINGS

FIG. 1 is a diagram illustrating a configuration of a switching control device according to a first embodiment.

FIG. 2 is a diagram illustrating a first example of a time waveform of a switching square wave for explaining a frequency change period.

FIG. 3 is a diagram illustrating a second example of the time waveform of the switching square wave for explaining the frequency change period.

FIG. 4 is a diagram for explaining a spectrum calculation method in short-time Fourier transform and an influence of a window function at a time of calculation.

FIG. 5 is a diagram for explaining switching control by the switching control device according to the first embodiment.

FIG. 6 is a diagram illustrating a process when switching square waves based on carrier frequencies illustrated in FIG. 5 are subjected to short-time Fourier transform,

FIG. 7 is a diagram for explaining an effect in a case where the switching control device according to the first embodiment is used.

FIG. 8 is a diagram illustrating a configuration of a DC-DC converter which is a first example of a power conversion device using the switching control device according to the first embodiment.

FIG. 9 is a diagram illustrating a configuration of an inverter which is a second example of the power conversion device using the switching control device according to the first embodiment.

FIG. 10 is a diagram illustrating a configuration of a switching control device according to a second embodiment.

FIG. 11 is a diagram illustrating an example of a time waveform of a switching square wave in the second embodiment.

FIG. 12 is a diagram comparing, regarding peak detection, a frequency characteristic of electromagnetic noise in a case of using the switching square wave in the second embodiment, a frequency characteristic of electromagnetic noise in a case of using a switching square wave of which a carrier frequency is fixed, and a frequency characteristic of electromagnetic noise in a case of using a switching square wave only a carrier frequency of which is variable.

FIG. 13 is a diagram comparing, regarding average detection, a frequency characteristic of electromagnetic noise in the case of using the switching square wave in the second embodiment, a frequency characteristic of electromagnetic noise in the case of using the switching square wave of which the carrier frequency is fixed, and a frequency characteristic of electromagnetic noise in the case of using the switching square wave only the carrier frequency of which is variable,

FIG. 14 is a diagram illustrating an example of a time waveform for explaining the switching square wave in the second embodiment.

FIG. 15 is a diagram illustrating a phase of a composite vector of two terms determined by switching times of a first carrier frequency on a complex plane.

FIG. 16 is a diagram illustrating a phase of a composite vector of two terms determined by switching times of a second carrier frequency on the complex plane.

FIG. 17 is a diagram illustrating an example of a time waveform for explaining a switching square wave in a third embodiment.

FIG. 18 is a diagram illustrating six phase differences illustrated in FIG. 17 on the complex plane.

FIG. 19 is a diagram illustrating an example of a time waveform of a switching square wave in a case where a frequency is variable.

FIG. 20 is a diagram illustrating an example of a time waveform of a switching square wave in a case where the frequency is fixed.

FIG. 21 is a diagram comparing, regarding peak detection, a frequency characteristic of electromagnetic noise in a case of using the switching square wave in the third embodiment, a frequency characteristic of electromagnetic noise in a case of using a switching square wave of which a carrier frequency is fixed, and a frequency characteristic of electromagnetic noise in a case of using a switching square wave only a carrier frequency of which is variable,

FIG. 22 is a diagram comparing, regarding average detection, a frequency characteristic of electromagnetic noise in the case of using the switching square wave in the third embodiment, a frequency characteristic of electromagnetic noise in the case of using the switching square wave of which the carrier frequency is fixed, and a frequency characteristic of electromagnetic noise in the case of using the switching square wave only the carrier frequency of which is variable.

FIG. 23 is a diagram illustrating an example of a hardware configuration for realizing functions of the switching control devices according to the first to third embodiments.

FIG. 24 is a diagram illustrating another example of the hardware configuration for realizing the functions of the switching control devices according to the first to third embodiments.

### DESCRIPTION OF EMBODIMENTS

Hereinafter, a switching control device and a power conversion device according to each embodiment will be described in detail with reference to the drawings.

### First Embodiment

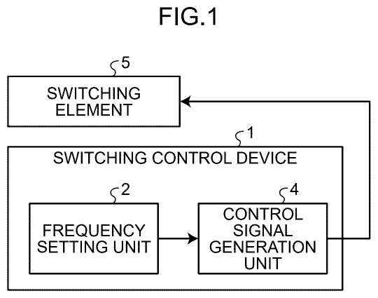

FIG. 1 is a diagram illustrating a configuration of a switching control device 1 according to a first embodiment. The switching control device 1 is a device that controls a switching operation performed by a switching element 5, and includes a frequency setting unit 2 that sets a plurality of types of carrier frequencies and a frequency change period T which is a period in which the carrier frequencies change. The switching element 5 is included in, for example, a power conversion circuit included in a power conversion device.

The switching control device 1 further includes a control signal generation unit 4 that generates a control signal for controlling the switching operation performed by the switching element 5 by transitioning the plurality of types of carrier frequencies in the frequency change period T. The control signal generation unit 4 is an example of a control unit. The frequency setting unit 2 sets the plurality of types of carrier frequencies so as to reduce switching noise of harmonic components when the switching element 5 performs the switching operation.

In a case where the power conversion circuit is an inverter, any of frequencies of several kHz to about 20 kHz is often used as a carrier frequency of general inverters. Alternatively, in a case where the power conversion circuit is a direct-current to direct-current (DC-DC) converter, any of carrier frequencies of wide range of values of several kHz to several MHz is often used in general DC-DC converters.

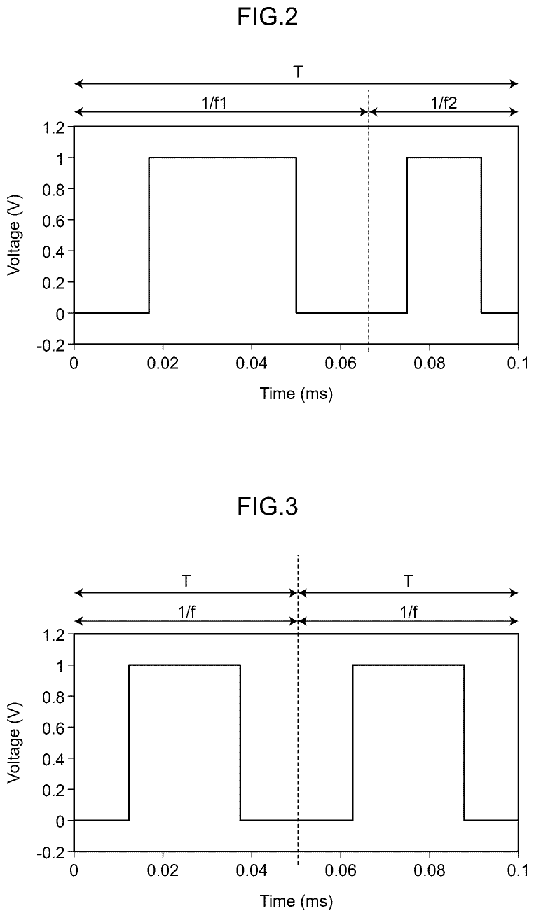

FIG. 2 is a diagram illustrating a first example of a time waveform of a switching square wave for explaining the frequency change period T. In FIG. 2, in order to simplify the description, the number of types of carrier frequencies is two, the two types of carrier frequencies f1 and f2 are f1=15 kHz and f2=30 kHz, and a duty ratio D, which is a ratio of on time over one period of the switching square wave based on the carrier frequencies f1 and f2, is D=0.5, FIG. 3 is a diagram illustrating a second example of the time waveform of the switching square wave for explaining the frequency change period T. FIG. 3 is a diagram for comparison with FIG. 2, and a fixed switching frequency f=20 KHz is used in FIG. 3. In each of FIGS. 2 and 3, the horizontal axis represents time and the vertical axis represents voltage.

In a case where the two types of carrier frequencies f1=15 kHz and f2=30 kHz are set by the frequency setting unit 2, for example, a switching square wave as illustrated in FIG. 2 is output from the control signal generation unit 4. In a case where the carrier frequency is fixed to a single carrier frequency f=20 kHz by the frequency setting unit 2, for example, a switching square wave as illustrated in FIG. 3 is output from the control signal generation unit 4. In the case of the second example illustrated in FIG. 3, the frequency change period T is T=1/f=0.05 ms. On the other hand, in the case of the first example illustrated in FIG. 2, regarding a control signal, a square wave is not a switching square wave in which an on time is repeated at a certain interval, but a switching square wave in which on times each associated with one of reciprocals of the two different carrier frequencies are repeated. Specifically, in the case of the first example illustrated in FIG. 2, the frequency change period T is determined from the sum of the reciprocals of the respective carrier frequencies, and is T=1/f1+1/f2=0.1 ms.

In the switching control device 1 according to the first embodiment, at least two types of carrier frequencies are set. In the first embodiment, the frequency change period T is set to be longer than a time width determined by a reciprocal of a resolution bandwidth (RBW). The at least two types of carrier frequencies may be determined in consideration also of some or all of hardware constraints such as performance of the switching element 5, loss of a passive component, and a thermal upper limit, and constraints of a microcomputer, or may be comprehensively determined in consideration of influence of a harmonic on a band of another order.

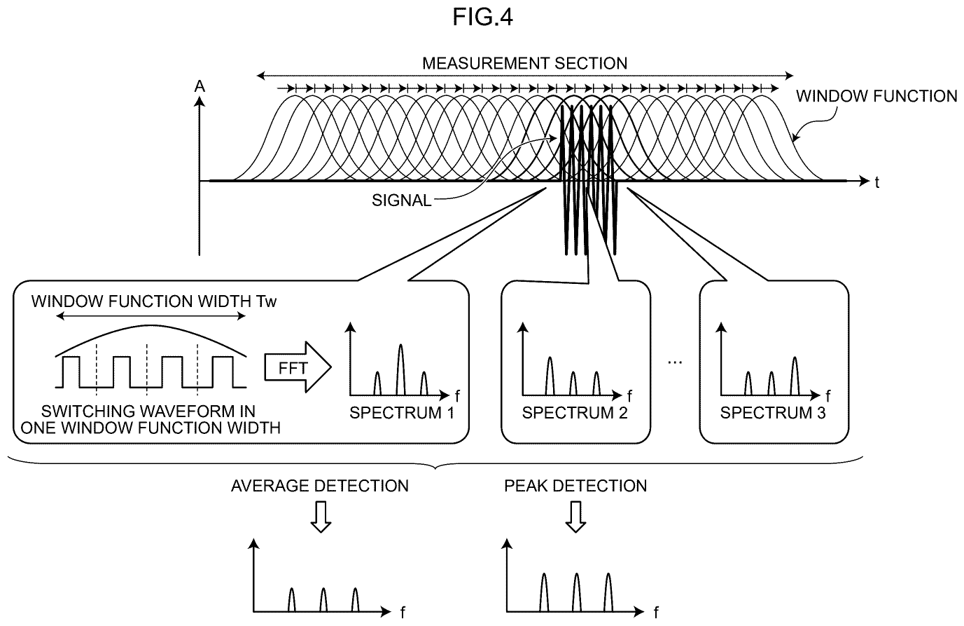

Next, a relationship between various detection methods and a noise reduction effect will be described. The detection methods include peak detection, quasi-peak detection, and average detection, FIG. 4 is a diagram for explaining a spectrum calculation method in short-time Fourier transform and an influence of a window function at a time of calculation.

In short-time Fourier transform used in an electromagnetic interference (EMI) receiver or the like, with respect to a time waveform acquired in a certain measurement time, a section of the time waveform is cut out by a window function and subjected to fast Fourier transform (FFT) to thereby acquire a spectrum in the section. Sections to be cut out by the window function as described above are shifted little by little to acquire a plurality of spectra. A peak value of each of the plurality of spectra is extracted, which is a spectrum obtained by peak detection, and an average value thereof is calculated, which is a spectrum obtained by average detection. The quasi-peak detection is a method in which a spectrum is obtained by adding a time constant circuit to the peak detection, and is basically a method in which a peak value is extracted. In the method of the first embodiment described below, a repetition period of switching is sufficiently fast with respect to a time constant, so that a spectrum substantially similar to that in the peak detection is obtained. Hereinafter, in this description, the peak detection and the quasi-peak detection are collectively referred to as “peak detection” as appropriate.

A window function width Tw which is a time width of the window function is determined by a reciprocal of the resolution bandwidth RBW, and takes various values depending on a standard or a band of interest.

Representative values of the resolution bandwidth RBW include 200 Hz, 1 kHz, 9 kHz, 10 kHz, 120 kHz, and 1 MHz. For example, in a band of 150 kHz or less, RBW may be defined as RBW=200 Hz, and in a band of 150 kHz to 30 MHz, RBW may be defined as RBW=9 kHz (or 10 kHz).

FIG. 4 illustrates spectrum 1, spectrum 2, and spectrum 3 as examples of spectra acquired by shifting sections cut out by the window function little by little. Among these three spectra 1 to 3, frequency bands with large spectrum values are different. Therefore, as illustrated in a lower portion of FIG. 4, the spectra are greatly different between a case where detection is performed by the average detection and a case where detection is performed by the peak detection, and it is difficult to obtain the noise reduction effect in the peak detection. In addition, in a case where the noise reduction effect is evaluated by the peak detection, it is necessary to strictly manage a relationship between a position of the window function and a peak position of the spectrum, and thus evaluation of the noise reduction effect is difficult, which is a problem. Therefore, in the first embodiment, the following method is proposed.

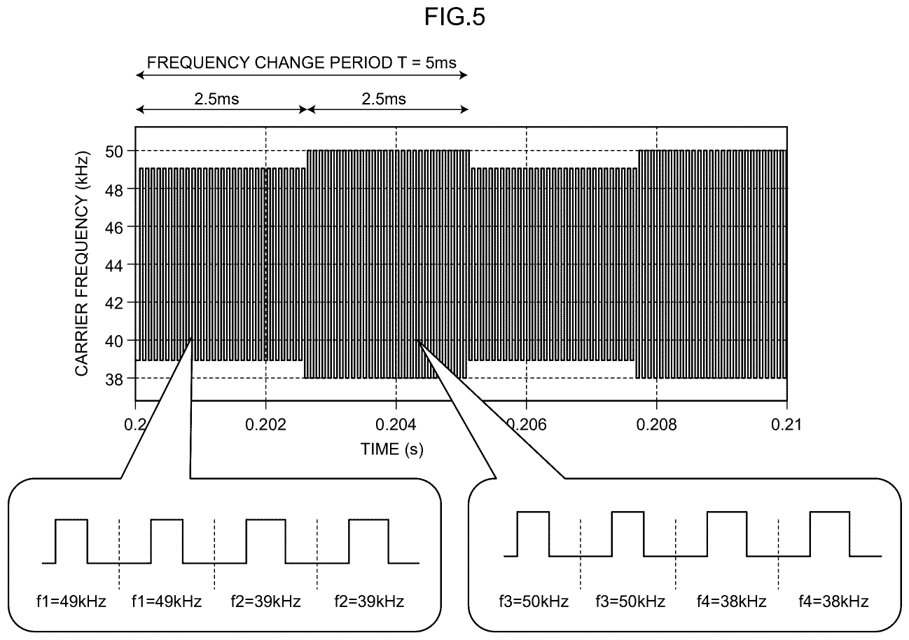

FIG. 5 is a diagram for explaining switching control by the switching control device 1 according to the first embodiment. More specifically, FIG. 5 illustrates temporal changes in carrier frequencies. In FIG. 5, the number of types of carrier frequencies is four, four types of carrier frequencies f1, f2, f3, and f4 are f1=49 kHz, f2=39 kHz, f3=50 kHz, and f4=38 kHz, and the frequency change period T is T=5 ms. In FIG. 5, the horizontal axis represents time, and the vertical axis represents value of carrier frequency.

As illustrated in FIG. 5, a pattern including f1, f1, f2, and f2 is repeated in a first 2.5-ms section, and a pattern including f3, f3, 14, and f4 is repeated in a subsequent 2.5-ms section. Then, the pattern including f1, f1, f2, and f2 is returned in a next 2.5-ms section, and the pattern including f3, 3, 4, and f4 is returned in a further next 2.5-ms section. Accordingly, the frequency change period T is 5 ms.

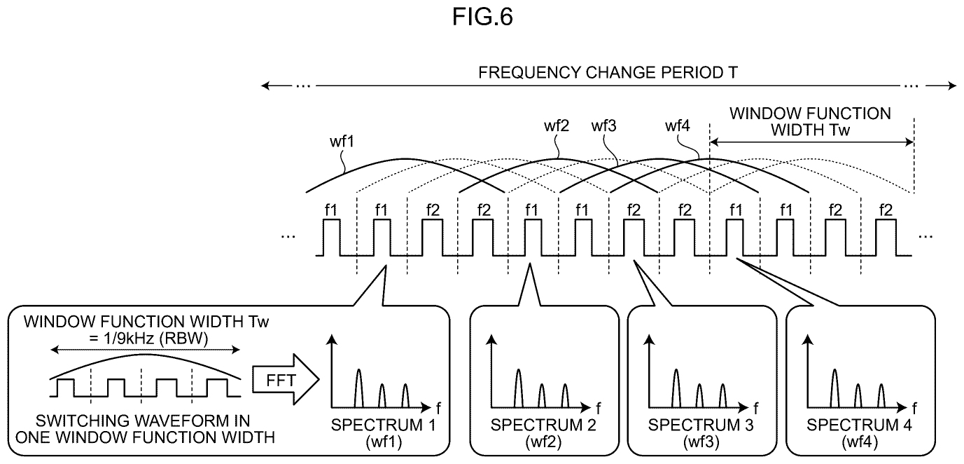

FIG. 6 is a diagram illustrating a process when switching square waves based on carrier frequencies illustrated in FIG. 5 are subjected to short-time Fourier transform. When RBW=9 kHz, then the window function width Tw=0.111 ms. Although calculation is omitted, a repetition period of the pattern including f1, f1, f2, and f2 is 0.0921 ms, and a repetition period of the pattern including f3, F3, f4, and f4 is 0.0926 ms. Accordingly, as illustrated in FIG. 6, four switching square waves are included in one window function width Tw. Since the frequency change period T=5 ms, there is a relationship of T>Tw between the frequency change period T and the window function width Tw. That is, in the first embodiment, the frequency change period T is set to be longer than the window function width Tw which is a time width determined by a reciprocal of the resolution bandwidth RBW.

Here, in a case of the switching square waves illustrated in FIG. 5 using the four types of carrier frequencies f1, f2, f3, and f4, the following 14 patterns are obtained as patterns of combinations of sections to be cut out with the window function width Tw.

<Pattern by carrier frequencies f1 and f2>
(a1) f1, f1, f2, and f2
(a2) f1, f2, f2, and f1
(a3) f2, f2, f1, and f1
(a4) f2, f1, f1, and f2
   <Pattern by Carrier Frequencies f3 and f4>
(a5) f3, f3, f4, and f4
(a6) f3, f4, f4, and f3
(a7) f4, f4, f3, and f3
(a8) f4, f3, f3, and f4

### <Other Patterns>

(a9) f1, f2, f2, and f3
(a10) f2, f2, f3, and f3
(a11) f2, f3, f3, and f4
(a12) f3, f4, f4, and f1
(a13) f4, f4, f1, and f1
(a14) f4, f1, f1, and f2

(a1) to (a4) are patterns that appear in a repetition section of f1 and f2 which is the first 2.5-ms section in FIG. 5. FIG. 6 illustrates spectrum 1 when the pattern of (a1) is subjected to FFT with a window function wf1, spectrum 2 when the pattern of (a4) is subjected to FFT with a window function wf2, spectrum 3 when the pattern of (a2) is subjected to FFT with a window function wf3, and spectrum 4 when the pattern of (a3) is subjected to FFT with a window function wf4. In these sections, both f1 and f2 appear twice in the patterns, and the same spectrum can be obtained even if the window function width Tw is shifted as illustrated in the figure.

In addition, (a5) to (a8) are patterns that appear in a repetition section of f3 and f4 which is the next 2.5-ms section subsequent to the first 2.5-ms section in FIG. 5, and in these sections, both f3 and f4 appear twice. Accordingly, in (a5) to (a8), the same spectrum is obtained even if the window function width Tw is shifted. In addition, (a9) to (a11) are patterns that appear at the moment of switching from the repetition section of f1 and f2 to the repetition section of f3 and f4, and (a12) to (a14) are patterns that appear at the moment of switching from the repetition section of f3 and 14 to the repetition section of f1 and f2. The spectra in these sections are slightly different from those in (a1) to (a4) or (a5) to (a8), but as can be understood from FIG. 5, are patterns that temporarily appear in sections in which the frequency change period T=5 ms, and also a ratio of the number of appearances in the frequency change period T is small, so that there is no significant influence on a spectrum calculation process. Note that, in a case where a difference between values of f1 and f3 and a difference between values of f2 and f4 are set to be small as in the example in FIG. 5 in this description, the influence of a difference in spectra is extremely small even at the moment of switching between the sets of carrier frequencies.

The patterns illustrated in FIGS. 5 and 6 are examples of patterns of switching square waves in the first embodiment. When a condition of the patterns of the switching square waves in the first embodiment is generalized, the condition can be expressed by the following formula (1A).

$$fave - RBW / 2 < fw < fave + RBW / 2 \qquad ( 1 A )$$

In the above formula (1A), fave is the average number of times of switching in sections of the frequency change period T, and fw is the average number of times of switching in sections cut out with the window function width Tw. In a case where a plurality of types of carrier frequencies are used as in the first embodiment, the average number of times of switching can be calculated by harmonic mean of the plurality of types of carrier frequencies. Note that the harmonic mean here also includes the concept of a weighted harmonic mean.

The above formula (1A) can also be expressed as |fw-fave|<RBW/2. This formula means that an absolute value of a difference between the average number of times of switching fave in the sections of the frequency change period T and the average number of times of switching fw in the sections cut out with the window function width Tw is smaller than ½ of the resolution bandwidth RBW. It is satisfactory as long as this condition and the above-described condition that the frequency change period T is longer than the window function width Tw which is a time width determined by a reciprocal of the resolution bandwidth RBW are satisfied. When a switching square wave in a control signal generated by the switching control device 1 satisfies these two conditions, the influence of the window function width Tw on a spectrum obtained by the average detection and a spectrum obtained by the peak detection can be reduced.

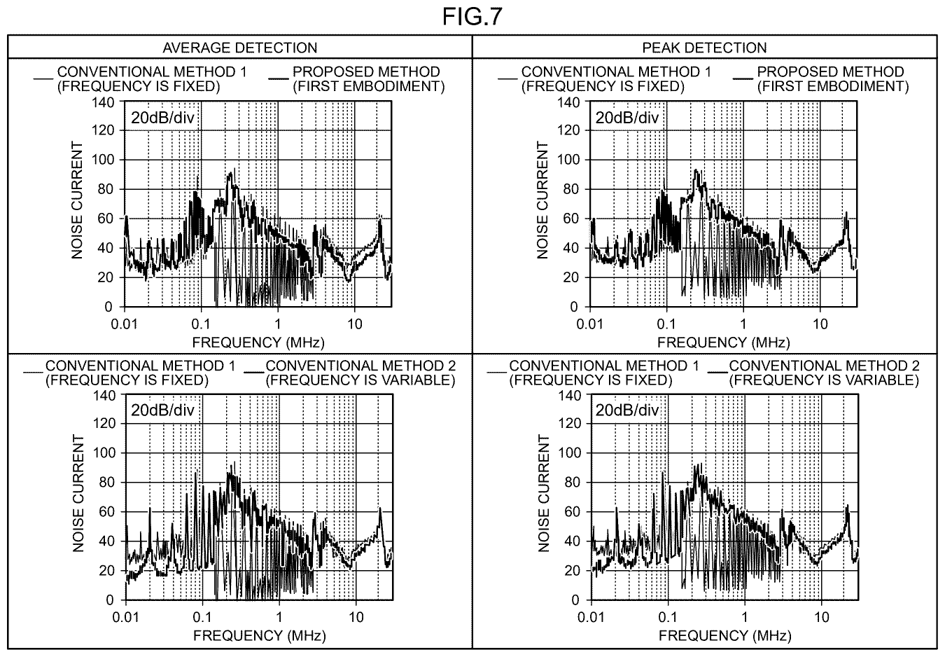

FIG. 7 is a diagram for explaining an effect in a case where the switching control device 1 according to the first embodiment is used. In FIG. 7, “conventional method 1 (frequency is fixed)” means that a switching square wave with a fixed carrier frequency is used. Hereinafter, conventional method 1 (frequency is fixed) is simply referred to as “conventional method 1”. A “proposed method (first embodiment)” is a method of the first embodiment in which the two carrier frequencies are switched in the two 2.5-ms sections illustrated in FIG. 5. Hereinafter, the proposed method (first embodiment) is simply referred to as a “proposed method”. In addition, “conventional method 2 (frequency is variable)” means that a pattern in which f1 and f2 are alternately repeated as f1, f2, f1, f2 . . . is used. This method is regarded as an example of a general frequency variable method. Hereinafter, conventional method 2 (frequency is variable) is simply referred to as “conventional method 2”.

In an upper left portion of FIG. 7, a frequency characteristic of a noise current by the average detection in a case of using the proposed method is indicated by a thick solid line, and a frequency characteristic of the noise current by the average detection in a case of using conventional method 1 is indicated by a thin solid line. In an upper right portion of FIG. 7, a frequency characteristic of the noise current by the peak detection in the case of using the proposed method is indicated by a thick solid line, and a frequency characteristic of the noise current by the peak detection in the case of using conventional method 1 is indicated by a thin solid line.

In a lower left portion of FIG. 7, a frequency characteristic of the noise current by the average detection in a case of using conventional method 2 is indicated by a thick solid line. For comparison, a characteristic curve by conventional method 1 illustrated in the upper left portion is indicated by a thin solid line. In a lower right portion of FIG. 7, a frequency characteristic of the noise current by the peak detection in the case of using conventional method 2 is indicated by a thick solid line. For comparison, a characteristic curve by conventional method 1 illustrated in the upper right portion is indicated by a thin solid line. In FIG. 7, each horizontal axis represents frequency, and each vertical axis represents level of noise current.

With the use of the proposed method, it is possible to “obtain a higher noise reduction effect under various measurement conditions” as described in the section of [Problems to be Solved by the Invention]. Here, as a specific example of “various measurement conditions”, the following cases are assumed: (1) a case where evaluation is performed by both the peak detection and the average detection; and (2) a case where evaluation is performed under different conditions of RBW. In general, the resolution bandwidth RBW is determined for each frequency band to be measured. For example, in a band of 150 kHz or less, RBW may be defined as RBW=200 Hz, and in a band of 150 kHz to 30 MHz, RBW may be defined as RBW=9 kHz (or 10 kHz) as described above. Each diagram of FIG. 7 is also measured with these values of RBW. Referring to FIG. 7 from these viewpoints, first, when the proposed method and conventional method 2 are compared with each other, the noise reduction effects thereof are maintained at a similar level in the peak detection, while in the average detection, a higher noise reduction effect is obtained in the proposed method (see around 1 MHz). Therefore, from the viewpoint of (1), the noise reduction effect is obtained more in the proposed method. In addition, when compared from the viewpoint of (2), in the band of 150 kHz to 30 MHz where RBW=9 kHz, noise reduction effects obtained in the proposed method and conventional method 2 are equivalent to each other. On the other hand, in the band of 150 kHz or less where RBW=200 Hz, a higher noise reduction effect is obtained in the proposed method (see around 90 kHz). Regarding this point, a similar tendency is exhibited in both cases in both the average detection and the peak detection. From the above, the proposed method can “obtain a higher noise reduction effect under various measurement conditions” from both the viewpoints (1) and (2). Note that, the example in FIG. 7 has been described by using the noise current, but the method in this description is not limited to the standards of the noise current,

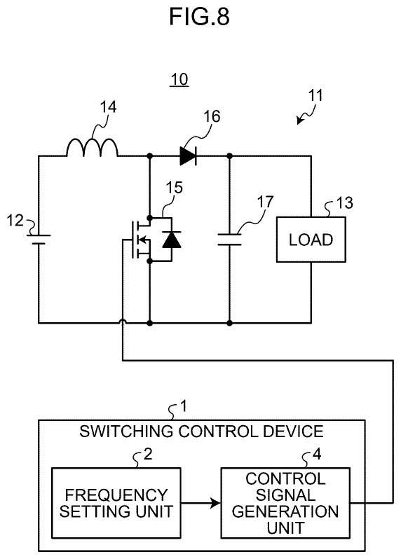

FIG. 8 is a diagram illustrating a configuration of a DC-DC converter 10 which is a first example of a power conversion device using the switching control device 1 according to the first embodiment. The DC-DC converter 10 includes the switching control device 1 described above and a boost chopper circuit 11 connected to a direct-current power supply 12 and a load 13. The boost chopper circuit 11 is an example of a power conversion circuit, and includes a reactor 14, a switching element 15, a diode 16, and a smoothing capacitor 17.

The switching element 15 performs a switching operation at timing in accordance with a control signal output from the control signal generation unit 4 included in the switching control device 1. The boost chopper circuit 11 boosts a voltage of input power from the direct-current power supply 12 and supplies output power of a desired voltage to the load 13. As the switching element 15, a semiconductor switching element such as a metal-oxide-semiconductor field-effect transistor (MOSFET) or an insulated gate bipolar transistor (IGBT), in which the diode 16 is connected in anti-parallel, is used.

The DC-DC converter 10 changes the duty ratio of the switching square wave in response to the state of the load 13 in order to obtain a desired direct-current voltage.

The power conversion circuit may be a device other than the boost chopper circuit 11, for example, may be a buck chopper circuit.

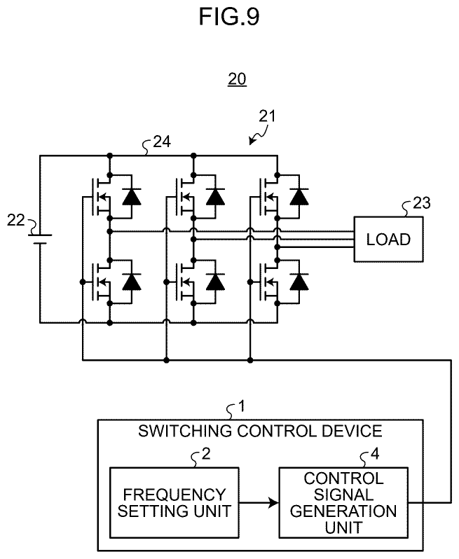

FIG. 9 is a diagram illustrating a configuration of an inverter 20 which is a second example of the power conversion device using the switching control device 1 according to the first embodiment. The inverter 20 includes the switching control device 1 according to the first embodiment, and an inverter main circuit 21 connected to a direct-current power supply 22 and a load 23. The inverter main circuit 21 is an example of a power conversion circuit, and includes switching elements 24.

Each switching element 24 performs a switching operation at timing in accordance with a control signal output from the control signal generation unit 4 included in the switching control device 1. The inverter main circuit 21 boosts a voltage of input power from the direct-current power supply 22 and supplies desired alternating-current output power to the load 23. As the switching element 24, a semiconductor switching element such as a MOSFET or an IGBT, in which a diode is connected in anti-parallel, is used.

The inverter main circuit 21 changes a duty ratio of the switching square wave in line with pulse width modulation control for applying, to the load 13, a desired alternating-current voltage of the inverter.

As described above, the switching control device according to the first embodiment is the switching control device that controls the switching operation performed by the switching element, and includes the frequency setting unit and the control unit. The frequency setting unit sets the plurality of types of carrier frequencies and the frequency change period, and the control unit controls the switching operation performed by the switching element by transitioning the plurality of types of carrier frequencies in the frequency change period. The frequency change period is set to be longer than a time width determined by a reciprocal of the resolution bandwidth. In addition, when the average number of times of switching in the sections of the frequency change period is denoted by fave, the average number of times of switching in the sections cut out with the time width is denoted by fw, the resolution bandwidth is denoted by RBW, and m is an integer of 2 or more, fw is set to satisfy a relationship of fave-RBW/2<fw<fave+RBW/2. With the use of the switching square wave set as described above, the influence of the window function width on a spectrum obtained by the average detection and a spectrum obtained by the peak detection can be reduced. Accordingly, use of the switching control device according to the first embodiment makes it possible to obtain a higher noise reduction effect under various measurement conditions.

### Second Embodiment

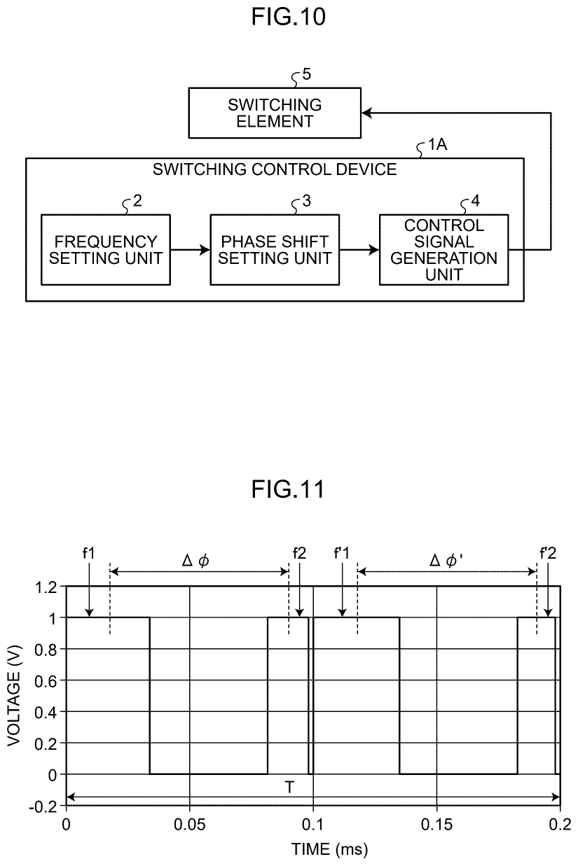

FIG. 10 is a diagram illustrating a configuration of a switching control device 1A according to a second embodiment. Comparing FIG. 10 with FIG. 1, the switching control device 1A illustrated in FIG. 10 is obtained by adding a phase shift setting unit 3 to the configuration in FIG. 1. The rest of the configuration is the same as or equivalent to that in FIG. 1. The same or equivalent components are denoted by the same reference numerals, and redundant descriptions thereof will be appropriately omitted. The switching control device 1A according to the second embodiment can be applied to various power conversion devices such as the DC-DC converter 10 illustrated in FIG. 8 and the inverter 20 illustrated in FIG. 9.

In the first embodiment, it has been described that the frequency setting unit 2 sets four types of carrier frequencies as an example of the plurality of types of carrier frequencies and sets the frequency change period T based on the four types of carrier frequencies. In the second embodiment, similarly, a case where the frequency setting unit 2 sets four types of carrier frequencies will be described as an example. Hereinafter, the four types of carrier frequencies are referred to as a first carrier frequency f1, a second carrier frequency f2, a third carrier frequency f′1, and a fourth carrier frequency f′2. That is, the first carrier frequency f1, the second carrier frequency f2, the third carrier frequency f′1, and the fourth carrier frequency f′2 are four types of carrier frequencies freely selected from the plurality of types of carrier frequencies.

In the first embodiment, it has been described that the switching square wave generated by the switching control device 1 satisfies the condition that the frequency change period T is longer than the window function width Tw determined by the reciprocal of the resolution bandwidth RBW and the condition indicated by the above formula (1A). Also the switching control device 1A according to the second embodiment is predicated on satisfying these two conditions. Under that condition, the phase shift setting unit 3 included in the switching control device 1A according to the second embodiment sets phase differences Δφ and Δφ′ between switching square waves determined by the four types of carrier frequencies.

FIG. 11 is a diagram illustrating an example of a time waveform of a switching square wave in the second embodiment. FIG. 11 illustrates a time waveform of a switching square wave in a control signal output from the control signal generation unit 4 according to the second embodiment. In FIG. 11, the horizontal axis represents time and the vertical axis represents voltage.

Specific examples of parameters set in FIG. 11 are as follows.

$$n = 46$$

$$T = 200 µs$$

$$D = 0.5$$

$$f 1 = 14.35 kHz ( first pulse )$$

$$f 2 = 33 kHz ( second pulse )$$

$$Δφ = 0.913 π ( between the first pulse and the second pulse )$$

$${f}^{′} 1 = 15 kHz ( third pulse )$$

$${f}^{′} 2 = 30 kHz ( fourth pulse )$$

$${Δφ}^{′} = 0.913 π ( between the third pulse and the fourth pulse )$$

In the specific examples in the second embodiment, the frequency setting unit 2 sets f1=14.35 kHz, f2=33 kHz, f1′=15 kHz, and f2′=30 kHz as the first carrier frequency f1, the second carrier frequency f2, the third carrier frequency f′1, and the fourth carrier frequency f′2, and sets T=200 μs as the frequency change period T. In addition, the frequency setting unit 2 sets the duty ratio D=0.5, the duty ratio being a ratio of on time over one period of switching. n is an integer of 1 or more, which is the order of a harmonic component for which noise reduction is desired. Here, n=46 is set. The phase shift setting unit 3 sets phase shift amounts Δφ and Δφ′=0.913n so as to reduce noise of a harmonic component around 460 kHz. The phase shift amounts Δφ and Δφ′ have the same meaning as the phase differences Δφ and Δφ′. That is, the frequency setting unit 2 sets the first carrier frequency f1, the second carrier frequency f2, the third carrier frequency f′1, the fourth carrier frequency f′2, the frequency change period T, and the duty ratio D depending on a harmonic component for which noise reduction is desired, and the phase shift setting unit 3 sets the phase differences Δφ and Δφ depending on the harmonic component.

When one period of the frequency change period T set by the frequency setting unit 2 is 2n, the phase difference Δφ is a difference obtained by converting, into a phase, a difference between an intermediate time between an on time and an off time of the switching square wave determined by the first carrier frequency f1 and an intermediate time between an on time and an off time of the switching square wave determined by the second carrier frequency f2. The same applies to the phase difference Δφ′.

The frequency setting unit 2 sets the first carrier frequency f1 and the second carrier frequency f2 and the phase shift setting unit 3 sets the phase difference Δφ so as to reduce switching noise of harmonic components when the switching element 5 performs the switching operation. Similarly, the frequency setting unit 2 sets the third carrier frequency f′1 and the fourth carrier frequency f′2 and the phase shift setting unit 3 sets the phase difference Δ′ so as to reduce switching noise of the harmonic components. The same applies to a case where the number of types of carrier frequencies is five or more. With any one type of carrier frequency as reference, the phase differences Δφ, Δφ′s . . . are set with respect to any one other type of carrier frequency, and a setting process of the phase differences Δφ, Δφ′, . . . is performed with respect to all types of carrier frequencies.

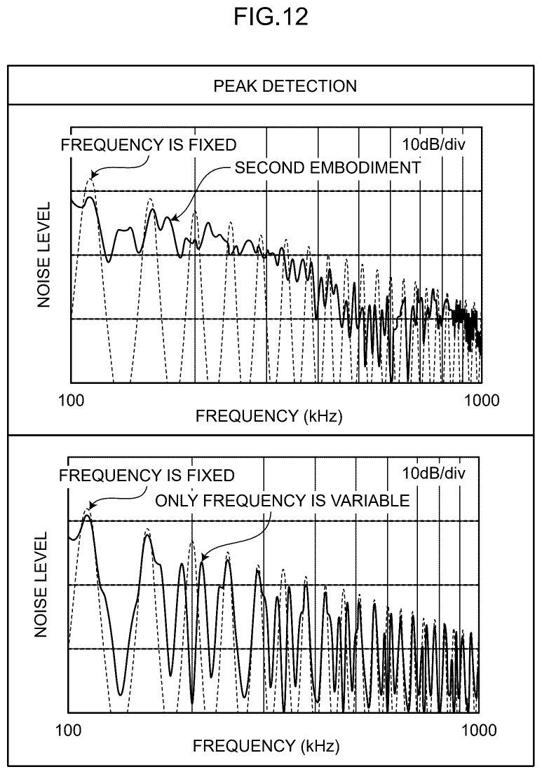

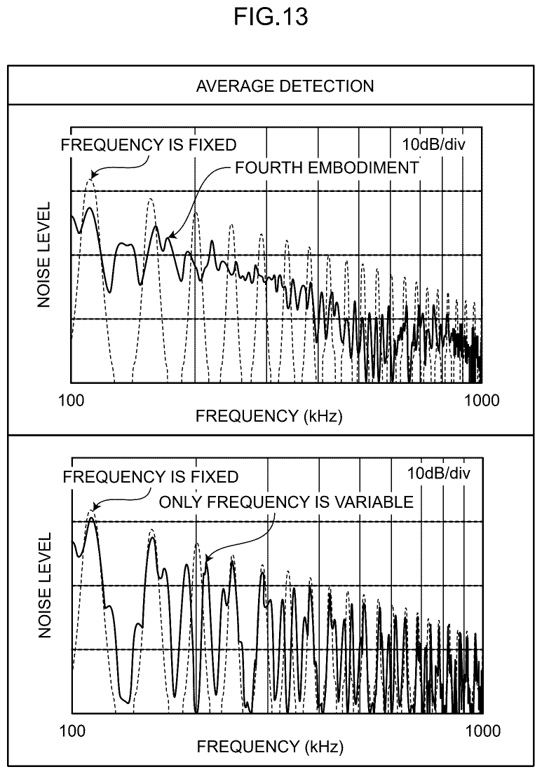

FIG. 12 is a diagram comparing, regarding the peak detection, a frequency characteristic of electromagnetic noise in a case of using a switching square wave in the second embodiment, a frequency characteristic of electromagnetic noise in a case of using a switching square wave of which a carrier frequency is fixed, and a frequency characteristic of electromagnetic noise in a case of using a switching square wave only a carrier frequency of which is variable. FIG. 13 is a diagram comparing, regarding the average detection, a frequency characteristic of electromagnetic noise in the case of using the switching square wave in the second embodiment, a frequency characteristic of electromagnetic noise in the case of using the switching square wave of which the carrier frequency is fixed, and a frequency characteristic of electromagnetic noise in the case of using the switching square wave only the carrier frequency of which is variable. In FIGS. 12 and 13, each horizontal axis represents frequency, and each vertical axis represents noise level (noise voltage).

It can be seen that, as illustrated in upper portions in FIGS. 12 and 13, noise is reduced in a certain range in a band from 400 kHz to 600 kHz including 460 kHz in the case where the four types of carrier frequencies f1, f2, f′1, and f′2 are set, in both the peak detection and the average detection, as compared with the case where the carrier frequency is fixed. In addition, as illustrated in lower portions in FIGS. 12 and 13, in a case where the phase difference Δφ is fixed even in a case where the carrier frequency is variable, a harmonic component in which noise is locally reduced is also observed, but noise of a harmonic component around 460 kHz is not reduced in the peak detection or the average detection, and a sufficient noise reduction effect is not obtained with a certain bandwidth. Since an upper limit value in electromagnetic noise standards is generally defined in a certain bandwidth, a method in which the switching control device 1A according to the second embodiment sets the four types of carrier frequencies f1, f2, f′1, and f′2, the frequency change period T, and the phase differences Δφ and Δφ′ is effective in evaluation of such an upper limit value in the standards.

The phase differences Δφ and Δφ′=0.913π in the second embodiment is merely an example, and there are a plurality of solutions of phase differences capable of reducing noise at 460 kHz as expressed by formula (4) to be described later. Although the reduction of noise at 460 kHz has been described so far as an example, a frequency at which noise is reduced is not limited to 460 kHz. The switching control device 1A may reduce noise in a band in which electromagnetic noise has a maximum value in a circuit resonance, for example.

In the second embodiment, the switching square wave is determined by using the variable frequency and the phase shift under a condition that the duty ratio is fixed. However, even if it is interpreted that the variable frequency and a variable duty are used under a condition that the phase is fixed, it is possible to define a switching square wave similar to the switching square wave determined by using the variable frequency and the phase shift under the condition that the duty ratio is fixed.

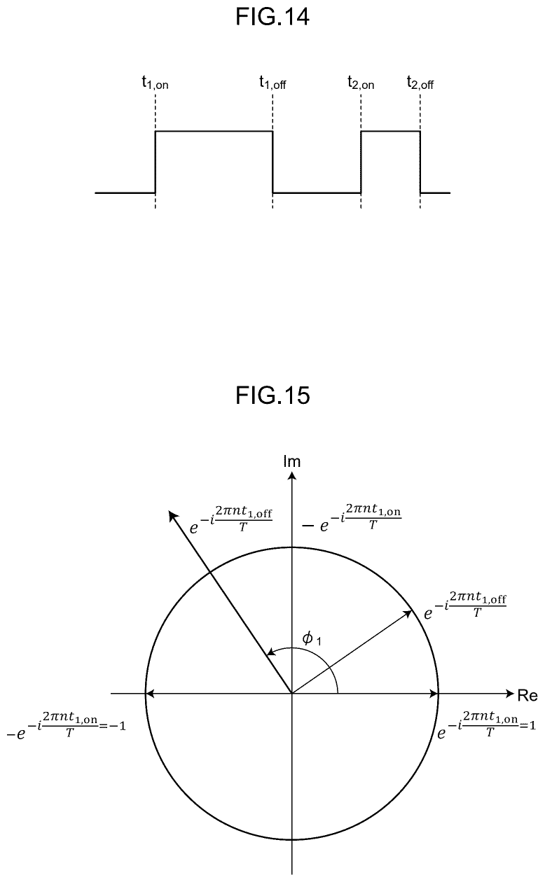

Next, a specific method for determining the phase differences Δφ and Δφ′ will be described. Here, the phase difference Δφ between the first carrier frequency f1 and the second carrier frequency f2 will be described. FIG. 14 is a diagram illustrating an example of a time waveform for explaining a switching square wave in the second embodiment. FIG. 14 illustrates a concept of a switching square wave. A harmonic noise component Aₙ of the switching square wave can be calculated by Fourier series expansion of a time waveform f(t) of the switching square wave as expressed by the following formula (1). f(t) is a function in which f(t)=1 holds only when time t is between t_{1,on} and t_{1,off}, and when time t is between t_{2,on} and t_{2,off}, and f(t)=0 holds otherwise. Time t_{1,on} is a time when the switching square wave is turned on by the first carrier frequency f1, time t_{1,off} is a time when the switching square wave is turned off by the first carrier frequency f1, time t_{2,on} is a time when the switching square wave is turned on by the second carrier frequency f2, and time t_{2,off} is a time when the switching square wave is turned off by the second carrier frequency f2.

$$\begin{matrix}Formula 1 & \\ \begin{matrix}{A}_{n} = \frac{1}{T} {\int }_{- T / 2}^{T / 2} f ( t ) {e}^{- i \frac{2 π n t}{T}} dt \\ = \frac{i}{2 π n} ( {e}^{- i \frac{2 π n {t}_{1 , off}}{T}} - {e}^{- i \frac{2 π n {t}_{1 , on}}{T}} + {e}^{- i \frac{2 π n {t}_{2 , off}}{T}} - {e}^{- i \frac{2 π n {t}_{2 , on}}{T}} )\end{matrix} & ( 1 )\end{matrix}$$

$$f ( t ) = \{ \begin{matrix}1 ( {t}_{1 , on} \leq t \leq {t}_{1 , off} , {t}_{2 , on} \leq t \leq {t}_{2 , off} ) \\ 0 ( otherwise )\end{matrix}$$

From formula (1), it can be seen that the harmonic noise component Aₙ can be expressed by using two terms exp{−i×(2πnt_{1,off})/T} and exp{−i×(2πnt_{1,on})/T} determined by switching times t_{1,on} and t_{1,off} of the first carrier frequency f1, and two terms exp{−i×(2πnt_{2,off})/T} and exp{−i×(2πnt_{2,on})/T} determined by switching times t_{2,on} and t_{2,off} of the second carrier frequency f2. Noise can be reduced by selecting the phase difference so that the absolute value of the sum of the two terms is decreased. Since coefficients of respective terms are equal, it is sufficient to consider a phase relationship between the respective terms on the complex plane. FIG. 15 is a diagram illustrating a phase φ₁ of a composite vector of two terms determined by switching times t_{1,on} and t_{1,off} of the first carrier frequency f1 on the complex plane. In FIG. 15, time t_{1,on} is a reference, and time t_{1,on}=0 holds. A relationship between the phase φ₁ and each variable is expressed by the following formula (2). For example, the switching control device 1A sets switching time t_{1,on} of the first carrier frequency f1 as a reference time, that is, time t_{1,on}=0, for formulas (1) and (2).

$$\begin{matrix}Formula 2 & \\ {ϕ}_{1} = - \frac{π n {t}_{1 , on}}{T} + \frac{π}{2} - \frac{π n {t}_{1 , off}}{T} & ( 2 )\end{matrix}$$

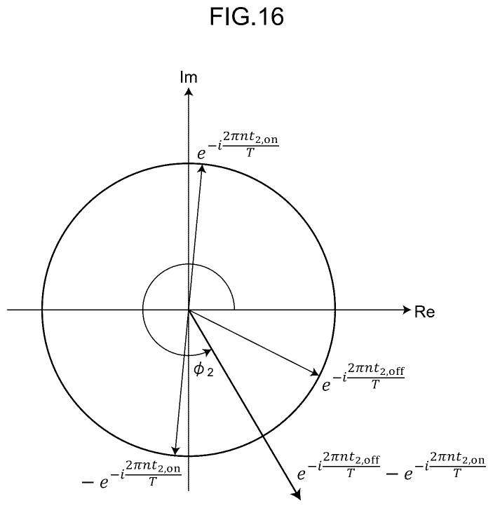

FIG. 16 is a diagram illustrating a phase oz of a composite vector of two terms determined by switching times t_{2,on} and t_{2,off} of the second carrier frequency f2 on the complex plane. A relationship between the phase φ₂ and each variable is expressed by the following formula (3).

$$\begin{matrix}Formula 3 & \\ {ϕ}_{2} = - \frac{π n {t}_{2 , on}}{T} + \frac{π}{2} - \frac{π n {t}_{2. off}}{T} & ( 3 )\end{matrix}$$

A condition that the harmonic noise component Aₙ decreases is that the composite vector of two terms determined by switching times t_{1,on} and t_{1,off} of the first carrier frequency f1 and the composite vector of two terms determined by switching times t_{2,on} and t_{1,off} of the second carrier frequency f2 cancel each other on the complex plane. That is, it is sufficient that a phase difference between the phase φ₁ and the phase oz is shifted by an odd multiple of π as expressed by the following formula (4). In a broader sense, it is sufficient that the phase difference between the phase φ₁ and the phase φ₂ is between π/2+2kπ and 3π/2+2kπ as expressed by the following formula (5). k is an integer of 1 or more. That is, in order to decrease the harmonic noise component Aₙ, the switching control device 1A approximates the phase difference between the phase φ₁ of the composite vector of the two terms determined by switching times t_{1,on} and t_{1,off} of the first carrier frequency f1 on the complex plane and the phase φ₂ of the composite vector of the two terms determined by switching times t_{2,on} and t_{2,off} of the second carrier frequency f2 on the complex plane to a value as close as possible to an odd multiple of π. In the second embodiment, n=46 is set in order to reduce noise at 460 kHz in the frequency change period T=200 μs. Although the phase difference Δφ=0.913π is set in order to reduce noise in a band having a certain range around 460 kHz, the phase difference Δφ=π may be set in a case where it is desired to reduce noise at 460 kHz in a narrower band.

$$\begin{matrix}Formula 4 & \\ \vert {ϕ}_{2} - {ϕ}_{1} \vert = ( 2 k - 1 ) π & ( 4 )\end{matrix}$$

$$\begin{matrix}Formula 5 & \\ \frac{π}{2} + 2 kn < \vert {ϕ}_{2} - {ϕ}_{1} \vert < \frac{3 π}{2} + 2 k π & ( 5 )\end{matrix}$$

As expressed by formulas (2) and (3), the phase φ₁ and the phase φ₂ include a term of π/2, but in a case where a relative phase difference of the phase difference Δφ=|φ₁−φ₂| is considered, (t_{1,on}+t_{1,off})/2 and (t_{2,on}+t_{2,off})/2 are important. That is, it is sufficient to consider a time difference between an intermediate time between an on time and an off time of a certain switching square wave and an intermediate time between an on time and an off time of the next switching square wave.

In the second embodiment, a phase shift amount is the phase difference Δφ, but the phase shift amount may be defined by a time difference Δt. For example, suppose that in the second embodiment, switching time t_{1,on} of the first carrier frequency f1 is set as the reference time, that is, t_{1,on}=0, then an on state is switched to an off state after time D/f1 corresponding to the duty ratio elapses, then the on time of the second carrier frequency f2 is set to 1/f1+Δt, and the on state is switched to the off state after time D/f2 corresponding to the duty ratio elapses from the on time of f2, respective times can be expressed as t_{1,on}=0, t_{1,off}=D/f1, t_{2,on}=1/f1+Δt, and t_{2,off}=1/f1+Δt+D/f1. Therefore, from formulas (2), (3), and (4), Δt can be expressed as the following formula (6).

$$\begin{matrix}Formula 6 & \\ Δ t = \frac{2 k - 1}{2 n} T - \frac{2 - D}{f 1} - \frac{D}{f 2} & ( 6 )\end{matrix}$$

At that time, when n=46, k=61, and D=0.5 in the second embodiment, a time difference corresponding to Δφ=0.913π is Δt=14.8 μs. Here, time t_{2,on} is shifted, but any of times t_{1,on}, t_{1,off}, t_{2,on}, and t_{1,off} may be shifted as long as a relative phase difference can be set. Regarding switching timing, switching time t_{1,on} of the first carrier frequency f1 may not be set as the reference time, and it is sufficient that the relative phase difference Δφ can be set, in order to obtain the noise reduction effect.

As described above, in the switching control device 1A according to the second embodiment, the switching square wave is determined by using the variable frequency and the phase shift, and thus the noise reduction effect is obtained also in the average detection. In addition, by using the switching control device 1A according to the second embodiment, it is possible to expect to obtain a similar effect even in a device using a measurement method other than short-time Fourier transform, such as a sweep-tuned spectrum analyzer.

As described above, the switching control device according to the second embodiment includes the phase shift setting unit that, when one of the plurality of types of carrier frequencies is the first carrier frequency, one of the plurality of types of carrier frequencies which is of different type from the first carrier frequency is the second carrier frequency, one which is different from the first and second carrier frequencies is the third carrier frequency, and one which is different from the first, second, and third carrier frequencies is the fourth carrier frequency, sets the phase difference between respective switching square waves determined by the first to fourth carrier frequencies. The phase shift setting unit sets the phase difference so as to reduce switching noise of harmonic components generated by the switching operation. Consequently, the switching control device according to the second embodiment can obtain a higher noise reduction effect under various measurement conditions. In addition, since the switching control device according to the second embodiment can change the carrier frequency and the phase difference in line with a harmonic component of a specific order, it is possible to more effectively reduce noise of the harmonic component of the specific order.

Note that the switching control device according to the second embodiment may be the following switching control device. That is, in a case where a phase is denoted by φᵢ, the phase being calculated on the basis of time t_{i,on} when a switching square wave which is a signal waveform of a control signal for controlling the switching operation is turned on by an i-th frequency fi among the plurality of types of carrier frequencies and time t_{i,off} when the switching square wave is turned off by the i-th frequency fi in the frequency change period, the phase shift setting unit may set the phase difference such that an absolute value of a phase difference between a phase φᵢ and a phase φᵢ₊₁ becomes π/m or more and 3π/m or less, i is an integer of 1 or more, and m means the number of types of carrier frequencies. The phase φᵢ may be defined by a formula of φᵢ=πnt_{i,on}/T+πnt_{i,off}/T. n is an integer of 1 or more and means the order of a harmonic component for which noise reduction is desired, and T means a frequency change period. The phase difference between the phase φ₁ and the phase φᵢ₊₁ may be 2π/m.

### Third Embodiment

In the second embodiment, the case where the frequency setting unit 2 sets four types of carrier frequencies in the switching control device 1A including the phase shift setting unit 3 has been described as an example. In a third embodiment, a case where the frequency setting unit 2 sets six types of carrier frequencies in the switching control device 1A including the phase shift setting unit 3 will be described as an example. The switching control device 1A according to the third embodiment can be applied to various power conversion devices such as the DC-DC converter 10 illustrated in FIG. 8 and the inverter 20 illustrated in FIG. 9.

Values of parameters in the third embodiment are as follows,

$$n = 33$$

$$T = 200 µs$$

$$f 1 = 21 kHz$$

$$f 2 = 27.8 kHz$$

$$f 3 = 61 kHz$$

$${φ}_{1} = 0.75 π$$

$${φ}_{2} = 1.69 π$$

$${φ}_{3} = 0.05 π$$

$${Δφ}_{12} = {φ}_{2} - {φ}_{1} = 0.94 π$$

$${Δφ}_{23} = {φ}_{3} - {φ}_{2} = - 1.64 π = 0.36 π$$

$${Δφ}_{31} = {φ}_{1} - {φ}_{3} = 0.7 π$$

$${f}^{′} 1 = 20 kHz$$

$${f}^{′} 2 = 30 kHz$$

$${f}^{′} 3 = 60 kHz$$

$${φ}_{1}^{′} = 0.75 π$$

$${φ}_{2}^{′} = 1.69 π$$

$${φ}_{3}^{′} = 0.05 π$$

$${Δφ}_{12}^{′} = {φ}_{2}^{′} - {φ}_{1}^{′} = 0.94 π$$

$${Δφ}_{23}^{′} = {φ}_{3}^{′} - {φ}_{2}^{′} = - 1.64 π = 0.36 π$$

$${Δφ}_{31}^{′} = {φ}_{1}^{′} - {φ}_{3}^{′} = 0.7 π$$

In the above parameters, n, T, f1, f2, φ₁, and φ₂ are those described in the second embodiment. f3 means a carrier frequency different from f1, f2, f′1, and f′2. f′3 means a carrier frequency different from f1, f2, f3, f′1, and f′2. φ₃ means a phase φ₁ a composite vector of two terms determined by switching times t_{3,on} and t_{3,off} of the carrier frequency f3 on the complex plane. Time t_{2,on} is a time when a switching square wave is turned on by the carrier frequency f3, and time t_{2,off} is a time when the switching square wave is turned off by the carrier frequency f3. Δφ₁₂ is a phase difference between φ₂ and φ₁ Δφ₂₃ is a phase difference between φ₃ and φ₂, and Δφ₃₁ is a phase difference between φ₁ and φ₃. The phase difference is defined in a range of 0 to 2π, inclusive. Descriptions of φ′1, φ′2, φ′3, Δφ′₁₂, Δφ′₂₃, and Δφ′₃₁ can be given similarly to those of φ₁, φ₂, φ₃, Δφ₁₂, Δφ₂₃, and Δφ₃₁.

In the third embodiment, the harmonic noise component Aₙ of the switching square wave is expressed by the following formula (7). A relationship between the phase φ₃ and each variable is expressed by the following formula (8). Δφᵢⱼ is expressed by the following formula (9). In formula (9), each of i and j is any one of 1, 2, and 3, and i is different from j. In a case where Δφᵢⱼ does not exist in the range of 0 to 2π, inclusive, Δφᵢⱼ is replaced with Δφᵢⱼ+2π or Δφᵢⱼ−2π such that Δφᵢⱼ exists in the range of 0 to 2n, inclusive.

$$\begin{matrix}Formula 7 & \\ \begin{matrix}{A}_{n} = \frac{1}{T} {\int }_{- T / 2}^{T / 2} f ( t ) {e}^{- i \frac{2 π n t}{T}} dt \\ = \frac{i}{2 π n} ( {e}^{- i \frac{2 π n {t}_{1 , off}}{T}} - {e}^{- i \frac{2 π n {t}_{1 , on}}{T}} + {e}^{- i \frac{2 π n {t}_{2 , off}}{T}} - \\ {e}^{- i \frac{2 π n {t}_{2 , on}}{T}} + {e}^{- i \frac{2 π n {t}_{3 , off}}{T}} - {e}^{- i \frac{2 π n {t}_{3 , on}}{T}} )\end{matrix} & ( 7 )\end{matrix}$$

$$f ( t ) = \{ \begin{matrix}1 ( {t}_{1 , on} \leq t \leq {t}_{1 , off} , {t}_{2 , on} \leq t \leq {t}_{2 , off} , {t}_{3 , on} \leq t \leq {t}_{3 , off} ) \\ 0 ( otherwise )\end{matrix}$$

$$\begin{matrix}Formula 8 & \\ {ϕ}_{3} = - \frac{π n {t}_{3 , on}}{T} + \frac{π}{2} - \frac{π n {t}_{3 , off}}{T} & ( 8 )\end{matrix}$$

$$\begin{matrix}Formula 9 & \\ {Δϕ}_{ij} = {ϕ}_{j} - {ϕ}_{i} & ( 9 )\end{matrix}$$

The switching control device according to the third embodiment can reduce noise of an n-th order harmonic component by setting the phase difference Δφᵢⱼ such that each Δφᵢⱼ satisfies the following formula (10),

$$\begin{matrix}Formula 10 & \\ \frac{π}{3} < {Δϕ}_{ij} < π & ( 10 )\end{matrix}$$

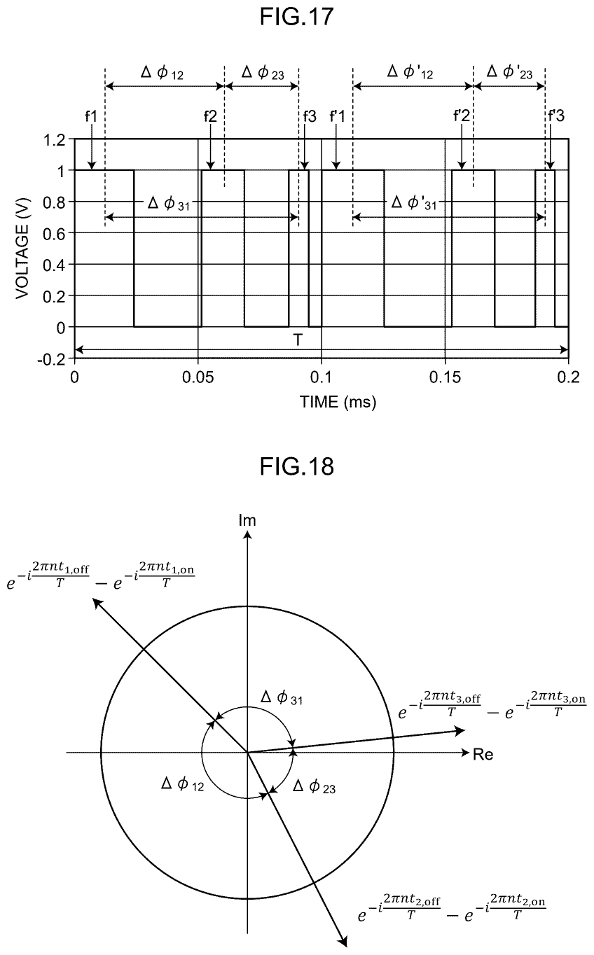

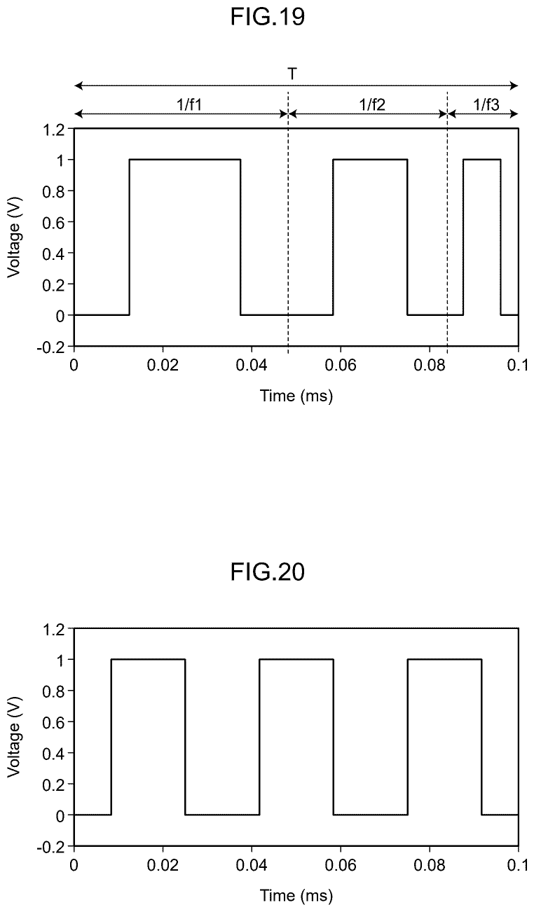

FIG. 17 is a diagram illustrating an example of a time waveform for explaining a switching square wave in the third embodiment. FIG. 17 is also a diagram for explaining six phase differences Δφ₁₂, Δφ₂₃, Δφ₃₁, Δφ′₁₂, Δφ′₂₃, and Δφ′₃₁. FIG. 18 is a diagram illustrating the six phase differences Δφ₁₂, Δφ₂₃, Δφ₃₁, Δφ′₁₂, Δφ′₂₃, and Δφ′₃₁ illustrated in FIG. 17 on the complex plane. FIG. 19 is a diagram illustrating an example of a time waveform of a switching square wave in a case where a frequency is variable. FIG. 20 is a diagram illustrating an example of a time waveform of a switching square wave in a case where the frequency is fixed. In each of FIGS. 17, 19, and 20, the horizontal axis represents time and the vertical axis represents voltage. In FIG. 20, 30 kHz is used as a fixed switching frequency. The fixed switching frequency of 30 kHz is selected in order to make the number of times of switching equivalent to the number of times of switching by the three types of carrier frequencies in FIG. 17, thereby making a switching loss condition comparable.

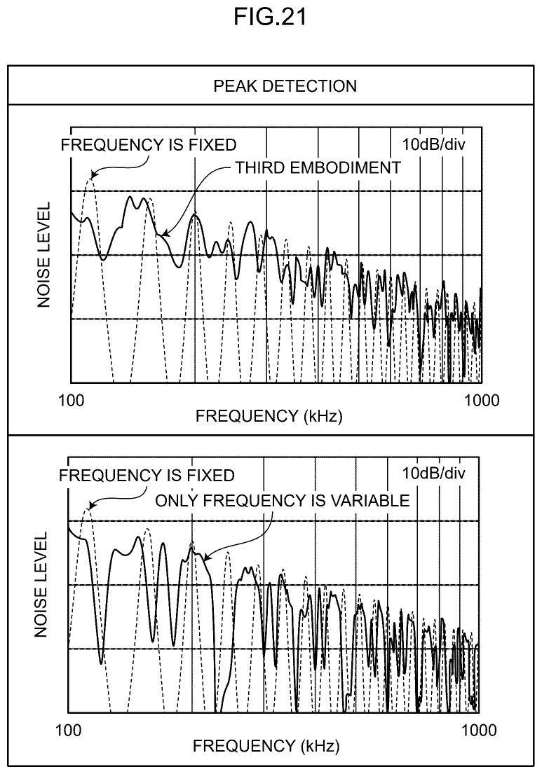

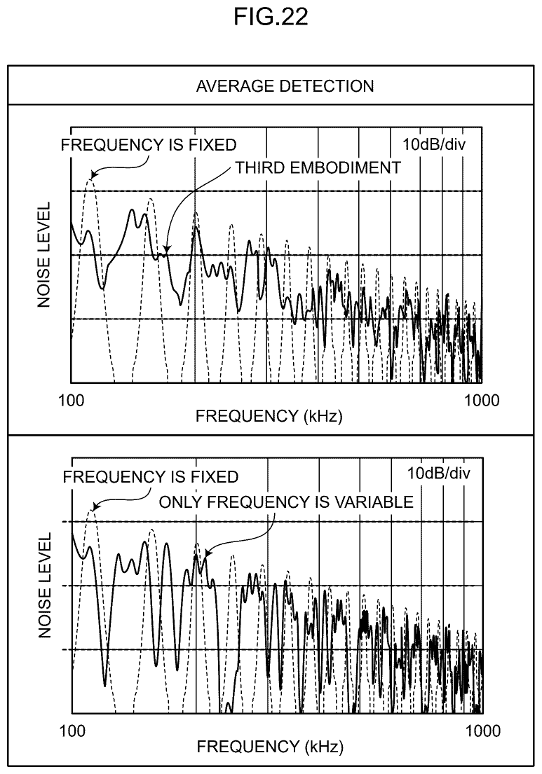

FIG. 21 is a diagram comparing, regarding the peak detection, a frequency characteristic of electromagnetic noise in a case of using the switching square wave in the third embodiment, a frequency characteristic of electromagnetic noise in a case of using a switching square wave of which a carrier frequency is fixed, and a frequency characteristic of electromagnetic noise in a case of using a switching square wave only a carrier frequency of which is variable. FIG. 22 is a diagram comparing, regarding the average detection, a frequency characteristic of electromagnetic noise in the case of using the switching square wave in the third embodiment, a frequency characteristic of electromagnetic noise in the case of using the switching square wave of which the carrier frequency is fixed, and a frequency characteristic of electromagnetic noise in the case of using the switching square wave only the carrier frequency of which is variable. In FIGS. 21 and 22, each horizontal axis represents frequency, and each vertical axis represents noise level (noise voltage).

It can be seen that, as illustrated in upper portions in FIGS. 21 and 22, noise is reduced in a certain range in a band from 310 kHz to 400 kHz including 330 kHz in the third embodiment, as compared with the case where the carrier frequency is fixed. In addition, as illustrated in upper and lower portions in FIGS. 21 and 22, even in a case where the carrier frequency is variable, if the phase differences Δφ and Δφ′ are fixed, a harmonic component of 330 kHz is larger than that in the third embodiment. That is, the method of the third embodiment is also effective in a case where noise of a harmonic component of a specific order is reduced.

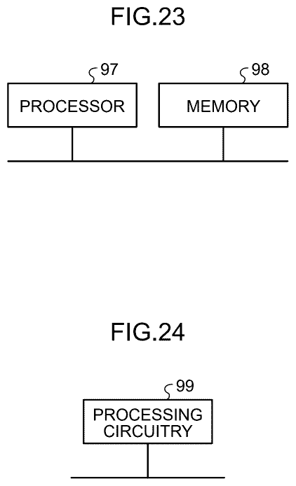

FIG. 23 is a diagram illustrating an example of a hardware configuration for realizing functions of the switching control devices 1 and 1A according to the first to third embodiments. That is, at least a part of functions of the frequency setting unit 2, the phase shift setting unit 3, and the control signal generation unit 4 of the first to third embodiments can be realized by a processor 97 that executes a program stored in a memory 98. Examples of the processor 97 include a central

processing unit (CPU, also referred to as a processing device, an arithmetic device, a microprocessor, a microcomputer, a processor, or a digital signal processor (DSP)), and system large scale integration (LSI). Examples of the memory 98 include a random access memory (RAM) and a read only memory (ROM).

In a case where at least a part of the functions of the frequency setting unit 2, the phase shift setting unit 3, and the control signal generation unit 4 of the first to third embodiments is realized by the processor 97, the at least part of the functions is realized by a combination of the processor 97 and software, firmware, or software and firmware. The software or the firmware is described as a program and stored in the memory 98. It can also be said that the program stored in the memory 98 causes a computer to execute at least a part of a procedure or method executed by the frequency setting unit 2, the phase shift setting unit 3, and the control signal generation unit 4 of the first to third embodiments.

FIG. 24 is a diagram illustrating another example of the hardware configuration for realizing the functions of the switching control devices 1 and 1A according to the first to third embodiments. That is, the functions of the switching control device 1 according to the first embodiment and the switching control device 1A according to the second and third embodiments can be realized by a processing circuitry 99 which is dedicated hardware.

The processing circuitry 99 is, for example, a single circuit, a composite circuit, a programmed processor, a parallel programmed processor, an application specific integrated circuit (ASIC), a field-programmable gate array (FPGA), or a combination thereof.

Regarding the functions of the switching control device 1 according to the first embodiment and the switching control device 1A according to the second and third embodiments, a part of the functions may be realized by dedicated hardware, and another part thereof may be realized by software or firmware. That is, a part of the functions of the frequency setting unit 2, the phase shift setting unit 3, and the control signal generation unit 4 of the first to third embodiments may be realized by the processor 97 and the memory 98 illustrated in FIG. 23, and the rest of the functions may be realized by the processing circuitry 99 illustrated in FIG. 24.

The configurations described in the embodiments above are merely examples and can be combined with other known technology and part of the configurations can be omitted or modified without departing from the gist thereof.

### REFERENCE SIGNS LIST

1, 1A switching control device; 2 frequency setting unit; 3 phase shift setting unit; 4 control signal generation unit; 5, 15, 24 switching element; 10 DC-DC converter; 11 boost chopper circuit; 12, 22 direct-current power supply; 13, 23 load; 14 reactor; 16 diode; 17 smoothing capacitor; 20 inverter; 21 inverter main circuit; 97 processor; 98 memory; 99 processing circuitry.

1. A switching control device that controls a switching operation performed by a switcher, the switching control device comprising:
a frequency setting circuitry to set a plurality of types of carrier frequencies and a frequency change period; and
a control circuitry to control a switching operation performed by the switcher by transitioning the plurality of types of carrier frequencies in the frequency change period, wherein
the frequency change period is longer than a time width determined by a reciprocal of a resolution bandwidth, and
when an average number of times of switching in sections of the frequency change period is denoted by fave, an average number of times of switching in sections cut out with the time width is denoted by fw, the resolution bandwidth is denoted by RBW, and m is an integer of 2 or more, the fw satisfies a relationship of:
fave−RBW/2<fw<fave+RBW/2.

2. The switching control device according to claim 1, wherein
the average number of times of switching is calculated by harmonic mean of the plurality of types of carrier frequencies.

3. The switching control device according to claim 1, wherein
the resolution bandwidth is any of 200 Hz, 1 kHz, 9 kHz, 10 kHz, 120 kHz, and 1 MHz.

4. The switching control device according to claim 1, comprising:
a phase shift setting circuitry to,
when one of the plurality of types of carrier frequencies is a first carrier frequency, one of the plurality of types of carrier frequencies that is different from the first carrier frequency is a second carrier frequency, one that is different from the first and second carrier frequencies is a third carrier frequency, and one that is different from the first, second, and third carrier frequencies is a fourth carrier frequency,
set a phase difference between respective switching square waves determined by the first to fourth carrier frequencies.

5. The switching control device according to claim 4, wherein
the phase shift setting circuitry sets the phase difference so as to reduce switching noise of a harmonic component generated by the switching operation.

6. The switching control device according to claim 5, wherein
the frequency setting circuitry sets the plurality of types of carrier frequencies, the frequency change period, and a duty ratio depending on the harmonic component, and
the phase shift setting circuitry sets the phase difference depending on the harmonic component.

7. The switching control device according to claim 4, wherein
in a case where a phase is denoted by φᵢ, the phase being calculated on a basis of time t_{i,on} when the switching square wave that is a signal waveform of a control signal for controlling the switching operation is turned on by an i-th frequency fi among the plurality of types of carrier frequencies and time t_{i,off} when a switching square wave is turned off by the i-th frequency fi in the frequency change period,
the phase shift setting circuitry sets the phase difference such that an absolute value of a phase difference between a phase φᵢ and a phase φᵢ₊₁ becomes π/m or more and 3 π/m or less,
i is an integer of 1 or more, and
m means a number of types of the carrier frequencies.

8. The switching control device according to claim 7, wherein
the phase φᵢ is defined by a formula of φᵢ=πnt_{i,on}/T+πnt_{i,off}/T,
n is an integer of 1 or more and means an order of a harmonic component for which noise reduction is desired, and
T means the frequency change period.

9. The switching control device according to claim 7, wherein
a phase difference between the phase φᵢ and the phase φᵢ₊₁ is 2π/m.

10. A power conversion device comprising:
the switching control device according to claim 1; and
a power conversion circuit including a switcher.
